(19) United States
(12) Patent Application Publication
(10) Pub. No.: US 2016/0270215 A1
(43) Pub. Date: Sep. 15, 2016

(54) FLEXIBLE ELECTRONICS DEVICE

(71) Applicant: EMPIRE TECHNOLOGY DEVELOPMENT LLC, Wilmington, DE (US)

(72) Inventor: Hiroshi GOTO, Ushiku-shi (JP)

(73) Assignee: EMPIRE TECHNOLOGY DEVELOPMENT LLC, Wilmington, DE (US)

(21) Appl. No.: 15/036,369

(22) PCT Filed: Nov. 18, 2013
(86) PCT No.: PCT/US2013/070627

§ 371 Date: May 12, 2016

(51) Int. Cl. H05K 1/02; H05K 3/12; H05K 3/00; H05K 1/03

(52) U.S. Cl. CPC H05K 1/0271; H05K 1/0393; H05K 1/0353; H05K 1/0306; H05K 3/1216; H05K 3/007; H05K 2201/0129

(57) ABSTRACT

Technologies are generally described for fabricating a multilayer substrate for a flexible electronic device. In example methods, at least one flexible film layer may be attached to a support film layer. At least one pattern may be formed on the at least one flexible film layer. The support film layer may be detached from the at least one flexible film layer. The support film layer may include a material with greater rigidity and lower thermal expansion coefficient than the at least one flexible film layer. The at least one flexible film layer may be attached to the support film layer using an adhesive such as a UV-curing adhesive. Further, the support film layer may be detached from the at least one flexible film layer by irradiating the UV-curing adhesive with ultraviolet light. The at least one flexible film may be attached to the support film layer using a roll-to-roll process.

### BACKGROUND

Unless otherwise indicated herein, the approaches described in this section are not prior art to the claims in this application and are not admitted to be prior art by inclusion in this section.

Recently, significant efforts have been made to develop flexible electronic devices, in which electronic devices can be formed on a flexible plastic film. The precision of pattern formation in the printing process may be an important factor that determines the device density, function, and performance. Thus, it may be important to ensure a precise alignment of the patterns formed in the individual printing processes.

In light of the above discussion, the present disclosure contemplates that there may be a need for a method for manufacturing a flexible electronic device that can reliably achieve alignment precision at submicron level when forming patterns on a flexible material by means of printing processes.

### SUMMARY

Technologies are generally described for fabricating a multilayer substrate for a flexible electronic device. The described technologies may be embodied in various systems, methods, devices, and products.

Various example methods described herein may include providing at least one flexible film layer on which at least one pattern is to be formed. A support film layer may be provided, and the at least one flexible film layer may be attached to the support film layer. The at least one pattern may be formed on the at least one flexible film layer. The support film layer may be detached from the at least one flexible film layer.

In some examples, methods for fabricating a multilayer substrate for a flexible electronic device are described. In example methods, at least one plastic film layer, on which at least one pattern is to be formed, may be provided. A glass film layer may be provided and the at least one plastic film layer may be attached to the glass film layer. The at least one pattern may be formed on the at least one plastic film layer. The glass film layer may be detached from the at least one plastic film layer.

In some examples, flexible electronic devices are described. Example devices may include at least one flexible film layer on which at least one pattern is formed. In the devices, a support film layer may be attached to the at least one flexible film layer, the support film layer including a material with greater rigidity and/or lower thermal expansion coefficient than the at least one flexible film layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 schematically shows plan and cross-sectional views of an example flexible electronic device formed on a support film layer;

FIG. 2 illustrates an example flow diagram of a method adapted to fabricate a multilayer substrate for a flexible electronic device;

FIG. 3 schematically shows a cross-sectional view of an example flexible film layer, on which at least one pattern is to be formed, and an example support film layer;

FIG. 4 schematically shows a cross-sectional view of an example flexible film layer and an example support film layer on which an adhesive material or film is formed;

FIG. 5 schematically shows a cross-sectional view of an example flexible film layer being attached to an example support film layer by a roll-to-roll process, with an adhesive material or film interposed therebetween;

FIGS. 6A to 6C schematically show cross-sectional views of example flexible electronic devices being built up by adding conductor and insulator layers and on a support film layer; and

FIG. 7 schematically shows a cross-sectional view of an example flexible electronic device, from which a support film layer is being detached by irradiating an ultraviolet light towards or heating an adhesive material or film;

all arranged in accordance with at least some embodiments described herein.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

This disclosure is generally drawn, inter alia, to flexible electronic devices, products, systems and methods, for example for in relation to a substrate, such as a multilayer substrate, for a flexible electronic device.

Briefly stated, technologies are generally described for fabricating a substrate for a flexible electronic device. In some example methods, at least one flexible film layer may be attached to a support film layer. At least one pattern may be formed on the at least one flexible film layer. The support film layer may be detached from the at least one flexible film layer. The support film layer may include a material with greater rigidity and lower thermal expansion coefficient than the at least one flexible film layer. The at least one flexible film layer may be attached to the support film layer using an adhesive such as a UV-curing adhesive. Further, the support film layer may be detached from the at least one flexible film layer by irradiating the UV-curing adhesive with ultraviolet light. The at least one flexible film may be attached to the support film layer using a roll-to-roll process.

In some examples, the flexible film layer may comprise a polymer, and may, for example, be a plastic film. In some embodiments, the flexible film layer may include at least one of PET (polyethylene terephthalate), PC (polycarbonate), and PEN (polyethylene naphthalate).

In some embodiments, the support film layer may include a material with a greater rigidity and a lower thermal expansion coefficient than the at least one flexible film layer. For example, the support film layer may include a glass material, such as an inorganic glass, for example an inorganic oxide glass such as a silicate glass material. In some examples, the support film layer comprises a borosilicate glass material and/or a quartz glass material.

In some embodiments, the at least one flexible film layer may be attached to the support film layer using a UV-curing adhesive. Further, the support film layer may be detached from the at least one flexible film layer by irradiating the UV-curing adhesive with ultraviolet light, for example where the adhesive is a UV-releasable adhesive. The ultraviolet light may have energy of less than about 100 mJ/cm2 and/or luminance in a range of about 10 mW/cm2 to about 30 mW/cm2.

In some embodiments, the at least one flexible film layer may be attached to the support film layer using a thermosetting adhesive. Further, the support film layer may be detached from the at least one flexible film layer by heating the adhesive. In this case, the adhesive may be heated at temperature in a range of about 40 degrees Celsius to about 60 degrees Celsius.

In some embodiments, attaching the at least one flexible film to the support film layer may include providing a double-sided adhesive film, attaching the support film layer to a first side of the double-sided adhesive film, and attaching the at least one flexible film layer to a second side of the double-sided adhesive film.

In some embodiments, the at least one flexible film may be attached to the support film layer using a roll-to-roll process.

In some embodiments, the at least one flexible film may be attached to the support film layer by applying an adhesive material onto the support film layer and/or the at least one flexible layer, and attaching the support film layer to the at least one flexible film layer.

In some embodiments, the at least one pattern may be formed on the at least one flexible film layer by a printed electronics method such as a gravure printing method, a screen printing method, or an ink jet printing method.

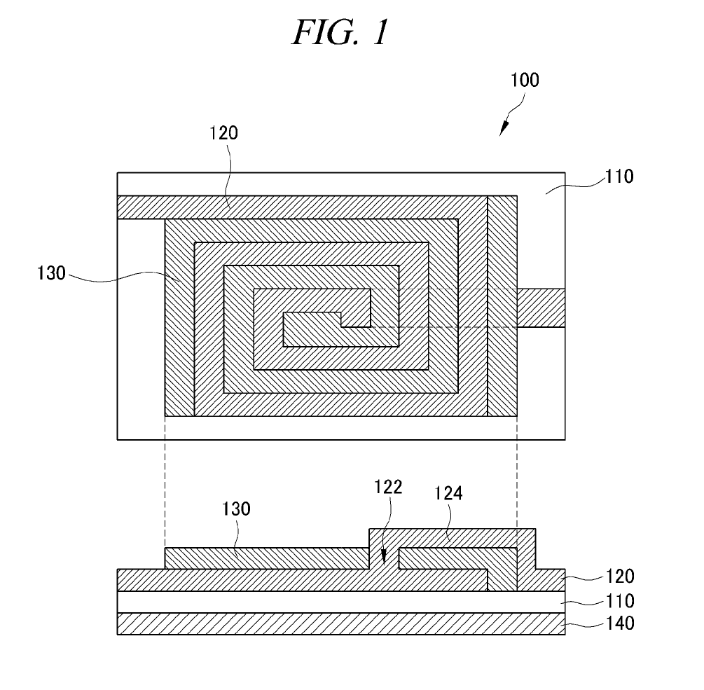

FIG. 1 schematically shows plan and cross-sectional views of an example flexible electronic device formed on a support film layer, arranged in accordance with at least some embodiments described herein. As depicted, an example flexible electronic device 100 may include a flexible film layer 110, on a upper surface of which one or more patterns including one or more conductor layers 120 and/or insulator layers 130 may be formed. Flexible electronic device 100 may further include a support film layer 140 attached to a lower surface of flexible film layer 110.

For the sake of explanation, FIG. 1 illustrates an induction circuit formed by patterning conductor layers 120 and insulator layers 130 on flexible film layer 110 attached to support film layer 140. However, any other types of circuits or devices including conductors, insulators, capacitors, resistors, inductors, fine metal circuits for touch sensors, organic solar cells, organic EL devices, etc. may be formed by patterning various materials or layers on flexible film layer 110 according to various desired features and implementations.

As described later in detail, in some embodiments, flexible electronic device 100 may be formed by a printed electronics method such as a gravure printing method, a screen printing method, an ink jet printing method, etc. For example, a conductive paste may be screen-printed on flexible film layer 110 to form conductor layer 120. Insulator layer 130 may be screen-printed on conductor layer 120 with a small access opening 122, which may be followed by a thermal treatment process for removing any volatile chemical components used in screen-printing as well as improving uniformity of the conductor layer 120 and the insulator layer 130. In one embodiment, the thermal treatment process may be performed at about 80 to 120 Celsius degrees for about 10 to 30 minutes. Then, another screen printing of conductor paste may be performed to form another conductor layer 124. A multilayer substrate may be formed on flexible film layer 110 by repeating the screen-printing and/or thermal treatment processes of conductor layers and insulator layers.

In some embodiments, the flexible film layer 110 may be any suitable flexible material having a lower rigidity (e.g., Young's modulus of about 1 GPa) than support film layer, 140 and a greater thermal expansion coefficient (e.g., about 10×10−5/K) than support film layer 140. For example, flexible film layer 110 may include at least one of PET (polyethylene terephthalate), PC (polycarbonate), and PEN (polyethylene naphthalate).

In some embodiments, support film layer 140 may include a material with a greater rigidity and a lower thermal expansion coefficient (e.g., a Young's modulus of in a range of about 65 to 90 GPa and a thermal expansion coefficient of about 3×10−6/K) than flexible film layer 110. In some embodiments, the support film layer itself may have a greater rigidity and a lower thermal expansion coefficient (e.g., a Young's modulus of in a range of about 65 to 90 GPa and a thermal expansion coefficient of about 3×10−6/K) than flexible film layer 110. For example, support film layer 140 may be a glass material such as a borosilicate glass material or a quartz glass material, or include a glass material such as a borosilicate glass material or a quartz glass material.

In some embodiments, flexible film layer 110 may have a thickness in a range of about 50 to about 200 micrometers, and in some examples about 100 micrometers, while the thickness of support film layer 140 may be chosen to be not greater than 100 micrometers, and in some examples in a range of about 50 to about 100 micrometers, since a certain level of flexibility may be needed in order to allow its use in a roll-to-roll process. Such thickness are not limiting.

Further, flexible film layer 110 and support film layer 140 may be attached to each other, for example, by applying an adhesive material to the surfaces of these layers and pressing them together, e.g., by a roll-to-roll process. Also, since flexible film layer 110 and support film layer 140 may be detached after completion of all the pattern formation processes on flexible film layer 110, it may be desirable to maintain the attachment between flexible film layer 110 and support film layer 140 reversible, e.g., using temporary bonding instead of permanent bonding. For this purpose, an adhesive material such as a UV-curing adhesive or a thermosetting adhesive may be used for attaching flexible film layer 110 and support film layer 140.

In case of using a UV-curing adhesive for attaching flexible film layer 110 and support film layer 140, its adhesive characteristics (e.g., bonding force) may decrease when ultraviolet light is irradiated on the UV-curing adhesive. For example, ultraviolet light with energy of less than about 100 mJ/cm2 and/or luminance in a range of about 10 mW/cm2 to about 30 mW/cm2 may be used for detaching support film layer 140 from flexible film layer 110.

In another embodiment, a thermosetting adhesive may be used for attaching flexible film layer 110 to support film layer 140. In this case, in order to detach support film layer 140 from flexible film layer 110, the adhesive may be heated at temperature in a range of about 40 degrees Celsius to about 60 degrees Celsius. For example, an adhesive used for a dicing tape in the process of dicing a semiconductor silicon wafer has the property of decreased adhesiveness responsive to heat treatment.

In some embodiments, the adhesive for attaching flexible film layer 110 to support film layer 140 may be applied in liquid or gel state on support film layer 140. In this case, any suitable coating equipment such as a slot-die coater, a bar coater, etc. may be used for applying the adhesive on support film layer 140. Flexible film layer 110 may be then attached onto the adhesive applied on support film layer 140.

In another embodiment, a double-sided adhesive film may be utilized to attach flexible film layer 110 to support film layer 140. In this case, support film layer 140 may be attached to one side of the double-sided adhesive film, and then flexible film layer 110 may be attached to the other side of the double-sided adhesive film. A roll-to-roll process may be used in pressing flexible film layer 110 against support film layer 140 for making sure that these layers are firmly attached to each other with the adhesive.

By using the multilayer substrate as shown in FIG. 1, support film layer 140 may serve to inhibit deformation of flexible film layer 110 in various manufacturing processes. Specifically, even in a roll-to-roll process where tension is applied to flexible film layer 110 or in a heat treatment process where the thermal expansion of flexible film layer 110 may be caused due to the heat treatment, support film layer 140 may serve to inhibit deformation of flexible film layer 110 and patterns formed on flexible film layer 100 due to the tension or thermal expansion. Thus, the deformation of flexible electronic device 100 can be considerably reduced compared to the case where flexible electronic device 100 is manufactured without support film layer 140. In one example, assuming that a plastic material (with a rigidity of about 1 GPa and a thermal expansion coefficient of about 10×10−5/K) is used as flexible film layer 110 and a glass carrier plate (with a rigidity in a range of about 65-90 GPa and a thermal expansion coefficient of about 3×10−6/K) is used as support film layer 140, deformation of flexible electronic device 100 can be reduced by a factor in a range of about 30 to about 50 compared to the case of manufacturing flexible electronic device 100 without using support film layer 140.

After completing the pattern formation processes on flexible film layer 110, support film layer 140 may be detached from flexible film layer 110. By using the above-described methods, support film layer 140 may be detached from flexible film layer 110 precisely without causing mechanical stress or lessening such mechanical stress (e.g., minimizing the amount of force, heat, and chemical treatment) applied to these layers. The surface of support film layer 140 may be subsequently cleaned by any suitable chemical and mechanical cleaning methods, so that support film layer 140 can be re-used for another manufacturing process (e.g., at least twice or more). In this manner, the material cost of using support film layer 140 in manufacturing flexible electronic device 100 can be reduced.

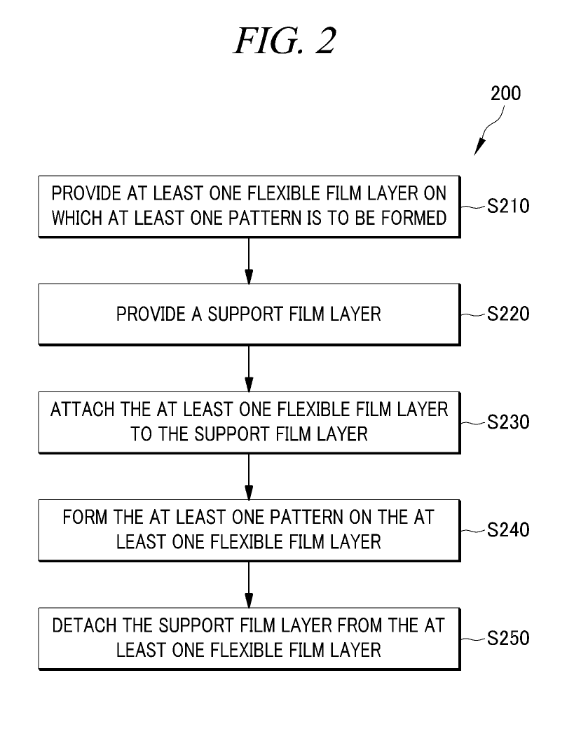

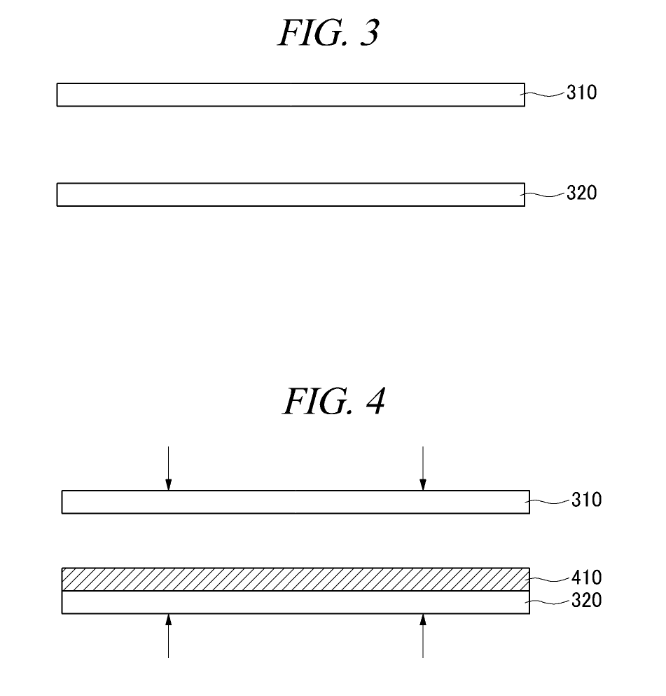

FIG. 2 illustrates an example flow diagram of a method adapted to fabricate a multilayer substrate for a flexible electronic device, arranged in accordance with at least some embodiments described herein. FIGS. 3 to 7 schematically show example processes for fabricating a multiplayer substrate for a flexible electronic device that is arranged in accordance with at least some embodiments described herein. FIG. 2 and FIGS. 3 to 7 will be discussed together as follows below.

An example method 200 in FIG. 2 may be implemented using, for example, a computing device including a processor adapted to control an equipment for manufacturing a flexible electronic device. Additionally and/or alternatively, method 200 may be implemented using, for example, a printed electronics equipment and/or a roll-to-roll (R2R) processing equipment.

Method 200 may include one or more operations, actions, or functions as illustrated by one or more of blocks S210, S220, S230, S240 and/or S250. Although illustrated as discrete blocks, various blocks may be divided into additional blocks, combined into fewer blocks, or eliminated, depending on the desired implementation. In some further examples, the various described blocks may be implemented as a parallel process instead of a sequential process, or as a combination thereof. Method 200 may begin at block S210, “PROVIDE AT LEAST ONE FLEXIBLE FILM LAYER ON WHICH AT LEAST ONE PATTERN IS TO BE FORMED.”

At block S210, at least one flexible film layer, on which at least one pattern is to be formed, may be provided. As depicted in FIG. 3, a flexible film layer 310 may be provided. In some embodiments, flexible film layer 310 may be made of any suitable flexible material having a lower rigidity (e.g., Young's modulus of about 1 GPa) and a greater thermal expansion coefficient (e.g., about 10×10−5/K) than a support film layer 320 which will be described later. For example, flexible film layer 310 may include at least one of PET, PC, and PEN. Block S210 may be followed by block S220, “PROVIDE A SUPPORT FILM LAYER.”

At block S220, a support film layer may be provided. As depicted in FIG. 3, support film layer 320 may be provided to be attached to flexible film layer 310. In some embodiments, support film layer 320 may include a material with a greater rigidity and a lower thermal expansion coefficient (e.g., a Young's modulus of in a range of about 65-90 GPa and a thermal expansion coefficient of about 3×10−6/K) than flexible film layer 310. For example, support film layer 320 may include a silicate glass material, such as a borosilicate glass material or a quartz glass material.

In some embodiments, flexible film layer 310 may have a thickness in a range of about 50 to about 200 micrometers, and in some examples may be about 100 micrometers in thickness. In some embodiments, the thickness of support film layer 320 may be chosen to be not greater than about 100 micrometers, and in some examples in a range from about 50 to about 100 micrometers, since a certain level of flexibility may be desired to facilitate use in a roll-to-roll process. Block S220 may be followed by block S230, “ATTACH THE AT LEAST ONE FLEXIBLE FILM LAYER TO THE SUPPORT FILM LAYER.”

At block S230, the at least one flexible film layer may be attached to the support film layer. As depicted in FIG. 4, support film layer 320 may be attached to flexible film layer 310. In some embodiments, flexible film layer 310 and support film layer 320 may be effectively attached to each other, for example, by applying an adhesive material 410 to one surface of support film layer 320 and pressing a surface of the flexible film layer 310 against the surface of the support film layer 320 with adhesive material 410 interposed therebetween.

In some embodiments, because flexible film layer 310 and support film layer 320 may be detached at a later time, it may be desired to keep the attachment between flexible film layer 310 and support film layer 320 reversible. For this purpose, an adhesive material such as a UV-curing adhesive or a thermosetting adhesive may be used for reversibly attaching flexible film layer 310 to support film layer 320.

In some embodiments, adhesive material 410 may be applied in liquid or gel state on a surface of support film layer 320. In this case, any suitable coating equipment such as a slot-die coater, a bar coater, etc. may be used for applying adhesive material 410 on the surface of the support film layer 320. Flexible film layer 310 may be then attached onto the adhesive material 410 applied on support film layer 320.

In another embodiment, a double-sided adhesive film 410 may be provided to attach flexible film layer 310 to support film layer 320. In this case, a surface of support film layer 320 may be attached to one side of double-sided adhesive film 410 (e.g., a lower side of adhesive film 410 as illustrated in FIG. 4), and a surface of flexible film layer 310 may be attached to the other side of the double-sided adhesive film (e.g., a upper side of adhesive film 410 as illustrated in FIG. 4).

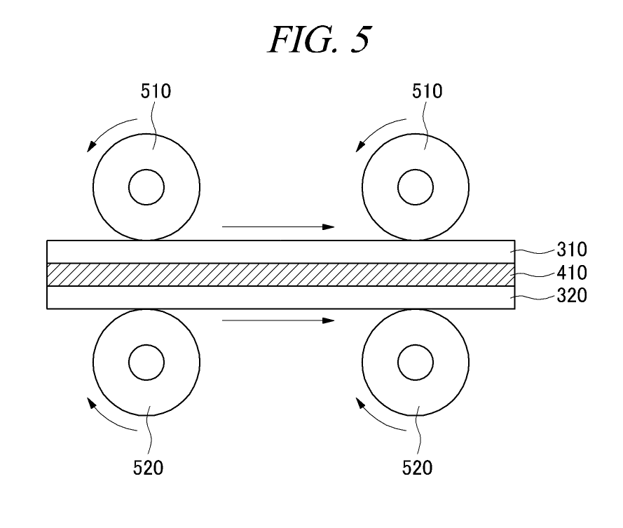

Further, a roll-to-roll process may be used in pressing flexible film layer 310 and support film layer 320 together to facilitate attachment to the adhesive material or the film 410. FIG. 5 schematically shows a cross-sectional view of an example flexible film layer being attached to an example support film layer by a roll-to-roll process, with an adhesive material or film interposed therebetween, arranged in accordance with at least some embodiments described herein. FIG. 5 depicts upper rollers 510, lower rollers 520, support film layer 320, flexible film layer 310, and adhesive material or adhesive film 410.

As depicted in FIG. 5, upper rollers 510 may be driven to rotate in a counter-clockwise direction while lower rollers 520 may be driven to rotate in a clockwise direction, such that flexible film layer 310 and support film layer 320 can be pressed against adhesive material or film 410. Because support film layer 320 has a greater rigidity than flexible film layer 310, support film layer 320 may serve to inhibit deformation of flexible film layer 310 even in a roll-to-roll process where tension is applied to flexible film layer 310. Block S230 may be followed by block S240, “FORM THE AT LEAST ONE PATTERN ON THE AT LEAST ONE FLEXIBLE FILM LAYER.”

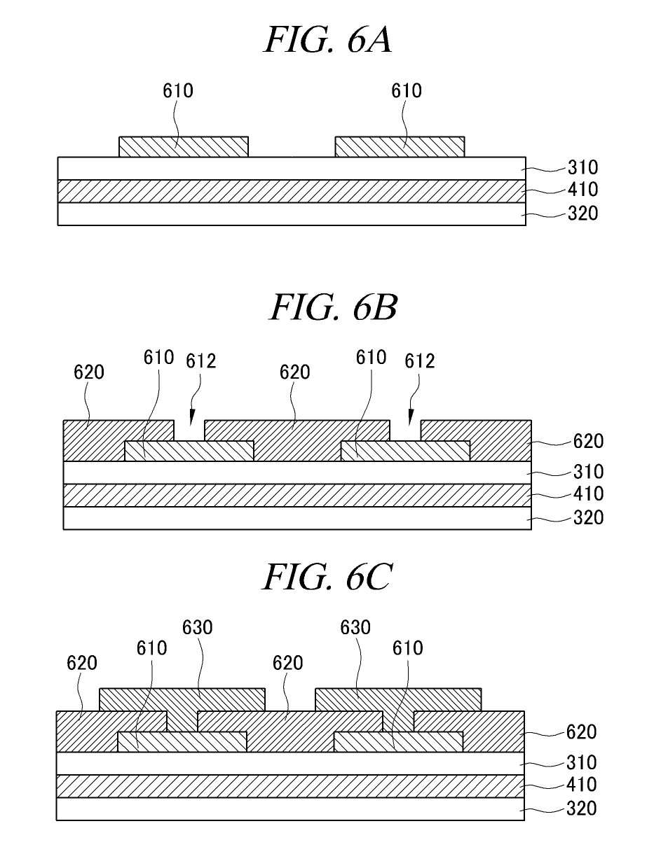

At block S240, the at least one pattern may be formed on the at least flexible film layer. FIGS. 6A to 6C schematically show cross-sectional views of example flexible electronic devices being built up by adding conductor and insulator layers and on a support film layer, arranged in accordance with at least some embodiments described herein. As depicted, in some embodiments, one or more patterns including one or more conductor layers 610 and 630 and/or insulator layers 620 may be formed on a surface of flexible film layer 310.

In some embodiments, the patterns on flexible film layer 310 may be formed by a printed electronics method such as a gravure printing method, a screen printing method, an ink jet printing method, etc. For example, as shown in FIG. 6A, a conductive paste may be screen-printed on a surface of flexible film layer 310 to form conductor layers 610. Further, as shown in FIG. 6B, insulator layers 620 may be screen-printed on a surface of conductor layers 610 with small access openings 612. As shown in FIG. 6C, another screen printing of conductor paste may be subsequently performed to form conductor layers 630 on insulator layers 620 and conductor layers 610. Although illustrated in FIG. 6C as a three-layer structure including layers 610 to 630, any other suitable structure having one or more layers may be formed on flexible film layer 310 by repeating the screen-printing processes of conductor layers and insulator layers.

For the sake of explanation, FIGS. 6A to 6C illustrate a flexible electronic device formed by patterning conductor layers 610 and 630 and insulator layers 620 on flexible film layer 310 attached to support film layer 320. However, any other types of circuits or devices including conductors, insulators, capacitors, resistors, inductors, etc. may be formed by patterning various materials or layers on flexible film layer 310 according to various requirements and implementations. Block S240 may be followed by block S250, “DETACH THE SUPPORT FILM LAYER FROM THE AT LEAST ONE FLEXIBLE FILM LAYER.”

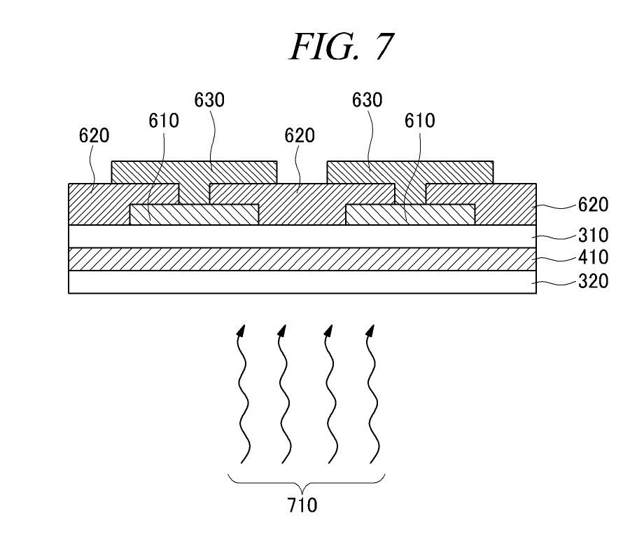

At block S250 the support film layer may be detached from the at least one flexible film layer. FIG. 7 schematically shows a cross-sectional view of an example flexible electronic device, from which a support film layer is being detached by irradiating an ultraviolet light towards or heating an adhesive material or film, arranged in accordance with at least some embodiments described herein. As shown in FIG. 7, in some embodiments, support film layer 320 may be detached from adhesive material or film 410 (or from flexible film layer 310) by irradiating ultraviolet light or heat 710 toward adhesive material or film 410.

In case of using a UV-curing adhesive 410 for attaching flexible film layer 310 to support film layer 320, adhesive properties may decreases when ultraviolet light 710 is irradiated on UV-curing adhesive 410. For example, ultraviolet light 710 with energy of less than about 100 mJ/cm2 and/or luminance in a range of about 10 mW/cm2 to about 30 mW/cm2 may be used for detaching support film layer 320 from flexible film layer 310. Alternatively, in case of using a thermosetting adhesive 410 for attaching flexible film layer 310 to support film layer 320, adhesive 410 may be heated at temperature in a range of about 40 degrees Celsius to about 60 degrees Celsius in order to detach support film layer 320 from flexible film layer 310.

As described above, after completing the pattern formation processes on flexible film layer 310, support film layer 320 may be detached from flexible film layer 310 precisely without causing mechanical stress or lessening such mechanical (e.g., minimizing the amount of force, heat, and chemical treatment) applied to these layers. The surface of support film layer 320 may be subsequently cleaned by any suitable chemical and mechanical cleaning methods to remove a part of adhesive material 410 attached to support film layer 320. In this manner, support film layer 320 can be re-used for another manufacturing process (e.g., at least twice or more), and thus, the material cost of using support film layer 320 in manufacturing flexible electronic device 100 can be minimized.

The spatial precision of pattern formation in the printing process may be an important factor that determines the device density, function, and performance. In order to form elements with a plurality of functional materials at high density on a same substrate, multiple printing processes may be used to form a multilayer structure, as well as to reduce the feature size. Some embodiments ensure a precise alignment of the patterns formed in the individual printing processes. For example, in the case where transistor circuits may be formed by 5-micron process, alignment precision of about 0.5 micrometer (which is about 1/10 of the feature size) may be achieved in some embodiments. Although 0.5-micrometer alignment precision can be achieved with some conventional semiconductor manufacturing technologies, problems may arise in printing-based pattern formation on a flexible material such as a plastic film. For example, alignment precision may be degraded due to film expansion and contraction caused by elastic properties or thermal deformations of the plastic film, which occur when a pattern is formed on a plastic film by a roll-to-roll process, or a heat treatment, without the use of a support film layer as described herein.

Some examples may appreciably reduce or substantially eliminate such problems, for example a reduction in alignment precision due to thermal and/or elastic distortion of a flexible film substrate, by using a support film layer as a carrier plate for a flexible film layer during the printing process, and then (optionally) removing the support film layer from the flexible film layer after the printing process is complete. Precision may be appreciably enhanced, allowing sub-micron (such as 0.5 micron) resolution to be achieved. The available choices of flexible film layer material may be increased, as thermal and elastic problems of certain materials may be avoided using the support film layer. Further, process options for a given flexible film layer material may be expanded, for example allowing higher temperatures and a wider range of applied forces to be used, through use of a support film layer as described herein. In some examples, the thermal and/or mechanical stability of the flexible film layer material during printing (and/or other processing) is improved by use of the support film layer as a carrier plate for the flexible film layer. If an optional drying process or other process is performed after printing, a support film layer may be removed from the flexible film layer after the drying or other process.

In some examples, the support film layer, once attached to the flexible film layer, may provide improved thermal and/or mechanical stability to the flexible film layer during pattern formation on the flexible film layer. For example, the support film layer may appreciably reduce thermal expansion (along directions in the plane of the layer), other thermal deformations, stretching, and the like, of the flexible film layer.

In some examples, the use of a support film layer as a carrier plate for a flexible film layer allows more precise pattern formation on the flexible film layer, for example alignment precision of less than one micron. The support film layer, such as a glass layer, may also be re-used after detaching the support film layer from the flexible film layer, which may reduce costs in a roll-to-roll process. A support film layer may be re-used a plurality of times, for example with different flexible film layers, achieving cost savings.

In some examples, the flexible film layer may be a plastic flexible film layer, such as a thermoplastic film. The flexible film layer may be attached to a support film layer during printing or other processing of the flexible film layer or components disposed thereon. Some example flexible film layers may comprise polyester, polycarbonate, polyethylene, other thermoplastic material, or a blend and/or copolymer thereof. Some example flexible film layers may comprise PET (polyethylene terephthalate), PEN (polyethylene naphthalate), and the like. In some examples, the flexible film layer may have a thickness in the range of 10 micrometers to 200 micrometers, and in some examples the thickness may be in the range of 50 micrometers to 150 micrometers, for example approximately 100 micrometers. In some examples, all ranges are inclusive.

In some examples, the flexible film layer may be a multilayer, for example a multilayer comprising one or more thermoplastic layers. In some examples, a plurality of support film layers may be used, for example a first support film layer being removable after a printing process, and a second support layer adjacent the flexible film layer being retained to facilitate further processing of the flexible film layer.

In some examples, the support film layer comprises a glass material, such as an inorganic oxide glass such as a silicate glass, such as borosilicate glass, and in some examples may be a thin glass sheet. In some examples, the support film layer may be relatively rigid, compared to the flexible film layer, and in some examples may have sufficient flexibility to be used in a roll-to-roll process. In some examples, a support film layer, such as a thin glass substrate, is attached to the flexible film layer to provide a carrier plate for the thin flexible substrate during a printing process, and is then removed from the flexible film layer. At least one pattern may be formed on the flexible film layer while the support film layer is attached to the flexible film layer.

In some examples, the support film layer may be a material having a higher rigidity and/or a lower thermal expansion coefficient than the flexible film layer. In some examples, the rigidity (Young's modulus) of the support film layer may be at least 10 times greater than that of the flexible film layer, and in some examples may be at least 50 times greater, and in some examples at least 100 times greater than that of the flexible film layer. In some examples, the thermal expansion coefficient of the support film layer may be less than one tenth than that of the flexible film layer. In some examples, material parameters and comparisons thereof may relate to a temperature, or range of temperatures, typical for the printing process used.

In some examples, the support film layer may comprise a metal (such as copper, silver, aluminum, steel, other metal, or metal alloy layer, for example in the form of a metal foil), a ceramic layer, a glass-ceramic layer, or a polymer layer (for example, a cross-linked or relatively high molecular weight polymer, compared with a polymeric flexible film layer), where the support film layer has higher rigidity and/or lower thermal expansivity than the flexible film layer.

In some examples, a glass support film layer is attached to a polymer (e.g. plastic) flexible film layer, a pattern formation process is used to achieve pattern formation on the flexible film layer, and the support glass film layer is then detached from the plastic flexible film layer after the pattern formation process is completed.

The support film layer may have sufficient flexibility to be attached to the flexible film layer in a roll-to-roll process, but otherwise may be appreciably less flexible than the flexible film layer. For example, the minimum bend radius of the support film layer may be approximately equal to, or less than, a radius of a roller used in the roll-to-roll process. In some examples, the minimum bend radius of the support film layer may be in a range 0.1 R to R, where R is the roller radius, for example in the range 0.3 R-R. In some examples, the minimum bend radius of the support film layer may be at least ten times greater than the minimum bend radius of the flexible film layer, in some examples at least 100 or 1000 times greater. In some examples, the minimum bend radius of the support film layer may be at least 1 cm.

In some examples, the support film layer may have a thermal expansion coefficient (e.g. for a temperature attained during the pattern formation process) that is one or more orders of magnitudes lower than that of the flexible film layer, under similar conditions (such as an ambient temperature or within a process temperature range). In some examples, the thermal expansion coefficient (for example, at a processing temperature or over a range of processing temperatures) may be less than one tenth than that of the flexible film layer, and in some examples the thermal expansion coefficient may be less than one hundredth than that of the flexible film layer.

In some examples, the thickness of the support film layer may be selected to achieve sufficient flexibility for a roll-to-roll process. In some examples, the support film layer thickness may be in the range of 50 to 500 micrometers. In some examples, for a glass support film layer, the glass thickness may be in the range 50 micrometers to 200 micrometers, such as within the range 50-100 micrometers, depending, for example, on the desired minimum bending radius, operating temperature, and desired lateral rigidity in the plane of the layer. In some examples, ranges may be inclusive, and in some examples range limits may be approximate.

In some examples, the support film layer may include organic materials, such as polymers. A support film layer may also include fibers, nanostructures (such as nanotubes), meshes, and other additional components chosen to enhance lateral stability (stability in the plane of the support film layer). Examples include fiber-reinforced polymers, carbon fiber composites, and the like. In some examples, lateral stability may only be desired in a single direction, for example the direction of motion of the layers through a processing apparatus. In some examples, the lateral stability may only be enhanced in the desired direction, for example using fibers preferentially aligned in that direction. In some examples, the support film layer may be a multilayer structure, such as a laminate, each layer having enhanced stability in a different lateral direction within the plane of the layer.

Adhesion between the substrate and the support film layer (for example, used as a carrier plate) may be reversible, allowing the substrate to be removed from the carrier plate. A releasable adhesive may be used to releasably attach a surface of the flexible film layer to a surface of the support film layer. A releasable adhesive may be released by application of heat, electromagnetic radiation, shear forces, a solvent, cooling, and the like to the adhesive to allow the flexible film layer to be detached from the support film layer. In some examples, heat and/or electromagnetic radiation may be applied to the adhesive through one or both of the adhered layers. In some examples, the adhesive may be a heat-releasable adhesive, such as a heat-sensitive adhesive with a bonding force that decreases when heat is applied to the adhesive. In some examples, the adhesive may be a UV-releasable adhesive with a bonding force that decreases when UV is applied to the adhesive.

In some examples, UV radiation may be used with UV-curable and UV-releasable adhesives. For example, the support film layer (and/or flexible film layer) may be partially transparent to UV radiation, for example as used to release a UV-releasable adhesive. UV radiation may be directed through the support film layer to release the support film layer from the flexible film layer. Some example adhesives include adhesives presently used in dicing tape employed in silicon wafer dicing processes. In some examples, a support film layer may be effectively attached to a flexible film layer (e.g. for the purposes of printing or other process step) without an adhesive layer, for example using electrostatic attraction or similar effects (e.g. van der Waals forces), direct formation of the support film layer on the flexible film layer (or vice versa), stiction or similar threshold effects, forces due to a thin film of fluid between adjacent films (e.g. capillary forces), heating of one or both films to achieve e.g. at least partial surface melting of at least one film, chemical interactions between adjacent film surfaces, and the like.

Some examples include methods for fabricating a substrate, such as a multilayer substrate, for a flexible electronic device. Some examples devices which may be fabricated using such methods include flexible electronic devices, such as displays (for example, flat panel displays and associated electronics, electroluminescent displays, organic material based light emitting displays (including OLED and light emitting polymer displays), and the like), energy sources (such as batteries, photovoltaic cells (such as solar cells), and the like), sensors (such as electronic sensors, for example optical sensors, capacitive sensors, and the like), antenna systems (such as antenna assemblies and components thereof, RFID (radiofrequency identification circuits), and the like), support electronics for other examples, and the like. Flexible electronic devices can be fabricated by patterning functional materials (such as electrical conductors, semiconductors, and the like, for example in a pattern) on the flexible film layer (such as a plastic film) using a printing process, such as screen printing process, gravure printing process, ink jet printing process, etc. to form an electronic circuit on the flexible film layer. In some examples, the support film layer may be optionally removed at some time between fabrication of components on the flexible film layer and use of the components in a device.

Some examples include an electronic circuit, for example an electronic circuit fabricated using a method such as described herein. An electronic circuit may include a transistor circuit, a sensor element (such as an optical sensor), a transducer, a wireless receiver and/or transmitter component, an antenna element (such as a radiative or receiver element), an electronic display element, an emissive element such as a light emitting diode (for example, an organic LED), a transponder, and the like. In some examples, a holograph may be formed on the flexible film layer, with higher resolution possible due to the use of a support film layer.

During an example printing process, the flexible film layer may be attached to a support film layer, which may subsequently be removed leaving an electronic circuit printed on the flexible film layer.

Some example apparatus for fabricating a flexible electronic circuit comprise a support film attachment device configured to attach a support film layer to a flexible film layer. The support film attachment device may include a roll-to-roll attachment device. Apparatus may also comprise a printer, configured to print an electronic circuit on the flexible film layer. Apparatus may also comprise a support film detachment device configured to detach the support film layer from the flexible film layer, providing a flexible electronic circuit comprising an electronic circuit printed on the flexible film layer. The electronic circuit may have features (such as sub-micron features) printed on a flexible film layer that (in the absence of the support film layer during the printing process) would lack, for example, the mechanical stability to support such features, for example during printing thereof or during an optional drying stage thereafter.

One skilled in the art will appreciate that, for this and other methods disclosed herein, the functions performed in the methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations may be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

The herein described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality, and any two components capable of being so associated can also be viewed as being “operably couplable,” to each other to achieve the desired functionality. Specific examples of operably couplable include but are not limited to physically mateable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A method to fabricate a substrate for a flexible electronic device, the method comprising:
providing at least one flexible film layer on which at least one pattern is to be formed;
providing a support film layer;
attaching the at least one flexible film layer to the support film layer;
forming the at least one pattern on the at least one flexible film layer; and
detaching the support film layer from the at least one flexible film layer.

2. The method of claim 1, wherein the support film layer is attached to the flexible film layer before forming the pattern on the flexible film layer, and the support film layer is detached from the flexible film layer after forming the at least one pattern on the flexible film layer.

3. The method of claim 1, wherein providing the at least one flexible film layer comprises providing the at least one flexible film layer including a thermoplastic material.

4. The method of claim 1, wherein providing the at least one flexible film layer comprises providing the at least one flexible film layer including one or more materials selected from the group consisting of PET (polyethylene terephthalate), PC (polycarbonate), and PEN (polyethylene naphthalate).

5. The method of claim 1, wherein providing the support film layer comprises providing the support film layer including a material with greater rigidity and lower thermal expansion coefficient than the flexible film layer.

6. The method of claim 1, wherein providing the support film layer comprises providing the support film layer including a silicate glass material, a borosilicate glass material, or a quartz glass material.

7. (canceled)

8. The method of claim 1, wherein attaching the at least one flexible film layer to the support film layer comprises attaching the at least one flexible film layer to the support film layer using an adhesive, the adhesive including a releasable adhesive.

9. The method of claim 1, wherein:
attaching the at least one flexible film layer to the support film layer comprises attaching the at least one flexible film layer to the support film layer using a UV-curing adhesive; and
detaching the support film layer from the at least one flexible film layer comprises irradiating the UV-curing adhesive with ultraviolet light with an energy of less than about 100 mJ/cm² or a luminance in a range of about 10 mW/cm² to about 30 mW/cm².

10-11. (canceled)

12. The method of claim 1, wherein:
attaching the at least one flexible film layer to the support film layer comprises attaching the at least one flexible film layer to the support film layer using a thermosetting adhesive; and
detaching the support film layer from the at least one flexible film layer comprises heating the thermosetting adhesive at a temperature in a range of about 40 degrees Celsius to about 60 degrees Celsius.

13-14. (canceled)

15. The method of claim 1, wherein attaching the at least one flexible film to the support film layer comprises:
providing a double-sided adhesive film;
attaching the support film layer to a first side of the double-sided adhesive film; and
attaching the at least one flexible film layer to a second side of the double-sided adhesive film.

16. (canceled)

17. The method of claim 1, wherein attaching the at least one flexible film to the support film layer comprises:
applying an adhesive material onto the support film layer; and
attaching the support film layer to the at least one flexible film layer.

18. The method of claim 1, wherein forming the at least one pattern on the at least one flexible film layer comprises forming the at least one pattern on the at least one flexible film layer by a printed electronics method, wherein the printed electronics method comprises at least one of a gravure printing method, a screen printing method, or an ink-jet printing method.

19. The method of claim 1, wherein attaching the at least one flexible film to the support film layer comprises attaching the at least one flexible film to the support film layer by a roll-to-roll process.

20. A flexible electronic device manufactured by the method of claim 1.

21. A method to fabricate a substrate for a flexible electronic device, the method comprising:
providing at least one plastic film layer on which at least one pattern is to be formed;
providing a glass film layer;
attaching the at least one plastic film layer to the glass film layer with a heat-releasable adhesive;
forming the at least one pattern on the at least one plastic film layer after attaching the at least one plastic film layer to the glass film layer; and
detaching the glass film layer from the at least one plastic film layer after forming the at least one pattern on the at least one plastic film layer, including heating the heat-releasable adhesive at temperature in a range of about 40 degrees Celsius to about 60 degrees Celsius.

22. The method of claim 21, wherein:
providing the at least one plastic film layer comprises providing the at least one plastic film layer including one or more materials selected from the group consisting of PET (polyethylene terephthalate), PC (polycarbonate), and PEN (polyethylene naphthalate); and
providing the glass film layer comprises providing the glass film layer including a borosilicate glass material or a quartz glass material.

23-27. (canceled)

28. The method of claim 21, wherein:
the heat-releasable adhesive is formed as a double-sided adhesive film; and
attaching the at least one plastic film layer to the glass film layer comprises:
attaching the glass film layer to a first side of the double-sided adhesive film;
attaching the at least one plastic film layer to a second side of the double-sided adhesive film; and
attaching the at least one plastic film layer to the glass film layer by a roll-to-roll process.

29-30. (canceled)

31. The method of claim 21, wherein forming the at least one pattern on the at least one plastic film layer comprises forming the at least one pattern on the at least one plastic film layer by a printed electronics method, wherein the printed electronics method includes at least one of a gravure printing method, a screen printing method, or an ink-jet printing method.

32. The method of claim 21, wherein attaching the at least one plastic film layer to the glass film layer includes attaching the at least one plastic film layer to the glass film layer by a roll-to-roll process.

33. A flexible electronic device manufactured by the method of claim 21.

34. A flexible electronic device comprising:
at least one flexible film layer on which at least one pattern is formed; and
a support film layer attached to the at least one flexible film layer, the support film layer including a material with greater rigidity and lower thermal expansion coefficient than the at least one flexible film layer.

35. The flexible electronic device of claim 34, wherein:
the at least one flexible film layer comprises one or more materials selected from the group consisting of PET (polyethylene terephthalate), PC (polycarbonate), and PEN (polyethylene naphthalate);
the support film layer comprises a borosilicate glass material or a quartz glass material
the at least one flexible film layer is attached to the support film layer using an adhesive; and
the adhesive includes a heat-releasable adhesive.

36-38. (canceled)

39. The flexible electronic device of claim 34, wherein the at least one flexible film is attached to the support film layer using a double-sided adhesive film, and wherein the support film layer is attached to a first side of the double-sided adhesive film and the at least one flexible film layer is attached to a second side of the double-sided adhesive film.
